(19) United States
(12) Patent Application Publication
(10) Pub. No.: US 2005/0248991 A1
(43) Pub. Date: Nov. 10, 2005

(54) Non-volatile memory device and programming method thereof

(76) Inventors: Kyeong-Han Lee, Gyeonggi-do (KR); June Lee, Seoul (KR)

Correspondence Address: MARGER JOHNSON & MCCOLLOM, P.C., 210 SW MORRISON STREET, SUITE 400, PORTLAND, OR, 97204, US

(21) Appl. No.: 10/977,384

(22) Filed: Oct. 28, 2004

(30) Foreign Application Priority Data
May 4, 2004 (KR) 2004-31466

(51) Int. Cl. G11C 11/34

(52) U.S. Cl. 365/185.28

(57) ABSTRACT

A non-volatile memory device according to some embodiments of the invention includes a number of memory cells and a word line voltage generator circuit. The word line voltage generator circuit generates a program voltage that is applied to the memory cells every program loop of a program cycle. The word line voltage generator circuit may generate a program voltage for one program loop that is different from a program voltage for each of the remaining program loops. Other embodiments are described and claimed.

### CROSS REFERENCE TO RELATED APPLICATIONS

This application claims priority from Korean Patent Application No. 2004-31466, filed on 4 May 2004, the content of which is hereby incorporated by reference in its entirety for all purposes.

### BACKGROUND OF THE INVENTION

1. Technical Field of the Invention

This disclosure relates to a semiconductor memory device, and, more particularly, to a program method for a non-volatile memory device.

2. Description of the Related Art

Semiconductor memories are usually considered to be the most vital microelectronic component of digital logic system design, such as computers and microprocessor-based applications ranging from satellites to consumer electronics. Therefore, advances in the fabrication of semiconductor memories including process enhancements and technology developments through the scaling for higher densities and faster speeds help establish performance standards for other digital logic families.

Semiconductor memory devices may be characterized as volatile random access memories (RAMs), or non-volatile memory devices. In RAMs, the logic information is stored either by setting up the logic state of a bistable flip-flop such as in a static random access memory (SRAM), or through the charging of a capacitor as in a dynamic random access memory (DRAM). In either case, the data are stored and can be read out as long as the power is applied, and are lost when the power is turned off; hence, they are called volatile memories.

Non-volatile memories, such as Mask Read-Only Memory (MROM), Programmable Read-Only Memory (PROM), Erasable Programmable Read-Only Memory (EPROM), and Electrically Erasable Programmable Read-Only Memory (EEPROM), are capable of storing the data, even with the power turned off. The non-volatile memory data storage mode may be permanent or reprogrammable, depending upon the fabrication technology used. Non-volatile memories are used for program and microcode storage in a wide variety of applications in the computer, avionics, telecommunications, and consumer electronics industries. A combination of single-chip volatile as well as non-volatile memory storage modes is also available in devices such as non-volatile SRAM (nvSRAM) for use in systems that require fast, programmable non-volatile memory. In addition, dozens of special memory architectures have evolved which contain some additional logic circuitry to optimize their performance for application-specific tasks.

In non-volatile memories, however, MROM, PROM, and EPROM are not free to be erased and written to by a system itself, so that it is not easy for general users to update stored contents. On the other hand, EEPROM is capable of being electrically erased or written. Application of the EEPROM is widened to an auxiliary memory or to system programming where continuous updates are needed (flash EEPROM). In particular, a flash EEPROM (hereinafter, referred to as a flash memory) exhibits a higher degree of integration than a conventional EEPROM and thus is advantageous in large auxiliary memory applications.

In general, a non-volatile memory device includes a number of memory cells, each of which consists of a floating gate transistor having a control gate and a floating gate. Each memory cell is programmed by injecting electrons in its floating gate and each memory cell is erased by discharging injected electrons in the floating gate into a bulk (or a substrate). Memory cells are programmed within a given program cycle, which is formed of a number of program loops.

Referring to FIG. 1, which shows a timing diagram for describing a program method of a conventional non-volatile memory device, each program loop is divided into a program period and a program verify period. A time (hereinafter, referred to as a program loop time) that is needed to perform each program loop is set the same with respect to all program loops (t1=t2=t3=t4). When the program loops are repeated, a program voltage Vpgm is stepwise increased by ΔV. This program method is called an Incremental Step Pulse Programming (ISPP) method. In each program loop, as understood from FIG. 1, a verify read voltage Vvfy, which is supplied to a selected row during each program period, is maintained constantly.

As the program loops are repeated, a threshold voltage of a memory cell is increasingly shifted into a target threshold voltage. Ideally, the threshold voltage increases smoothly at a fixed rate in response to a raise in the program voltage Vpgm. However, within an initial period of the program cycle, the threshold voltage of the memory cell increases relatively quickly with respect to increments in the program voltage while it increases at a slower rate with respect to increments of the program voltage within the remaining period of the program cycle.

For example, referring to FIG. 2, which shows a threshold voltage variation when a memory cell is programmed, the threshold voltage of the memory cell increases relatively quickly with respect to increments of the program voltage within first and second program loops t1, t2 of the program cycle while it increases at a slower speed with respect to the increment of the program voltage within the remaining program loops t3, t4. In other words, the amount that the threshold voltage is shifted in the first and second program loops t1, t2 is different than the amount it is shifted in the remaining program loops t3, t4 (ΔVth1, ΔVth2>ΔVth3, ΔVth4). Herein, the threshold voltage increments (ΔVth3 and ΔVth4) of the remaining program loops (e.g., the third and fourth program loops) are similar or identical to one another, and thus are linear with respect to the program voltage increment.

When all program loops are set to the same program loop time, it is difficult to distribute threshold voltages of the programmed memory cells within a desired threshold voltage range due to the above-described cause. That is, the threshold voltage distribution of programmed memory cells is widened.

Embodiments of the invention address these and other disadvantages of the conventional art.

### SUMMARY OF THE INVENTION

Some embodiments of the invention provide a non-volatile memory device and a program method capable of controlling a threshold voltage distribution density. Other embodiments of the invention to provide a non-volatile memory device and a program method capable of controlling program times of program loops differently.

### BRIEF DESCRIPTION OF THE DRAWINGS

A more complete appreciation of the invention, and many of the attendant advantages thereof, will become readily apparent and better understood by reference to the following detailed description that should be considered in conjuction with the accompanying drawings in which like reference symbols indicate the same or similar components, and that are briefly described below.

FIG. 1 is a timing diagram illustrating a program method of a conventional non-volatile memory device.

FIG. 2 is a diagram illustrating the threshold voltage variation when a memory cell is programmed according to FIG. 1.

FIG. 3 is a schematic block diagram illustrating a non-volatile memory device according to some embodiments of the invention.

FIG. 4 is a schematic block diagram illustrating the memory cell array and the page buffer circuit of FIG. 3.

FIG. 5 is a circuit diagram further illustrating the page buffer circuit of FIG. 4.

FIG. 6 is a circuit diagram illustrating the pass/fail check circuit of FIG. 3.

FIG. 7 is a timing diagram illustrating a program method according to some embodiments of the invention.

FIG. 8 is a diagram illustrating the threshold voltage variation according to the program method of FIG. 7.

FIG. 9A is a diagram illustrating the threshold voltage distribution according to the conventional program method.

FIG. 9B is a diagram illustrating the threshold voltage distribution according to some embodiments of the invention.

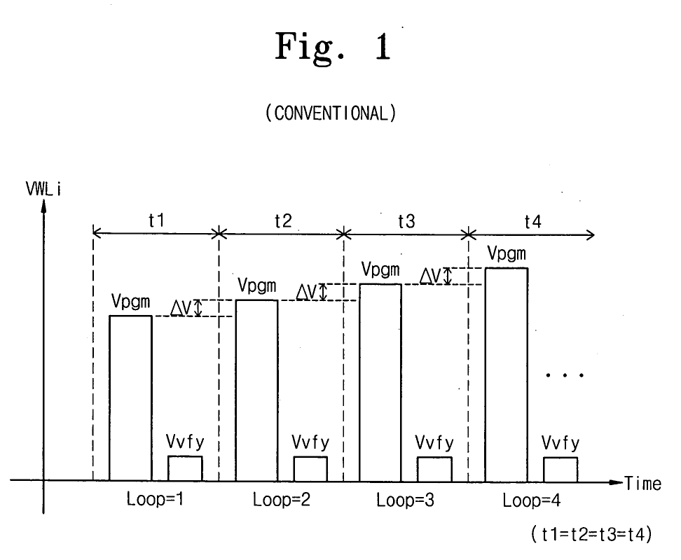

### DETAILED DESCRIPTION OF THE INVENTION

Some embodiments of the invention will be more fully described with reference to the attached drawings.

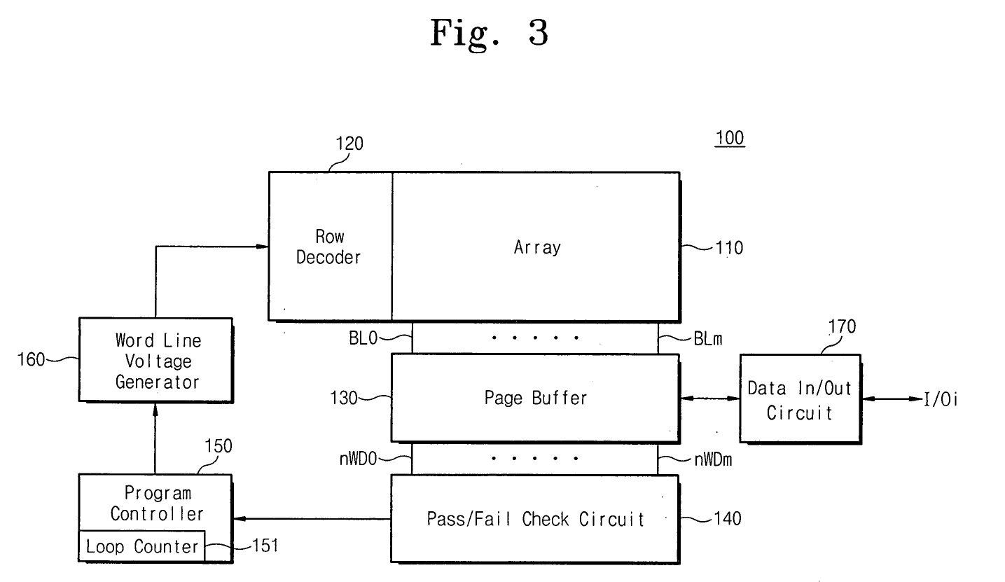

FIG. 3 is a schematic block diagram illustrating a non-volatile memory device according to some embodiments of the invention. The non-volatile memory device according to the embodiments illustrated in FIG. 3 is a NAND-type flash memory device. However, it will be apparent to those skilled in the art that other embodiments of the invention may be applied to other memory devices, such as MROM, PROM, NOR-type flash memory devices, FRAM, and the like.

Referring to FIG. 3, the non-volatile memory device 100 according to some embodiments of the invention includes a memory cell array 110 that has memory cells arranged in a matrix of rows (or referred to as word lines or pages) and columns (or referred to as bit lines). A row decoder circuit 120 selects one of the rows (or word lines) of the memory cell array 110 in response to a row address and drives the selected row (or word line) with a word line voltage from a word line voltage generator circuit 160.

A page buffer circuit 130 is electrically connected to the memory cell array 110 via bit lines BL0-BLm. The page buffer circuit 130 performs various roles according to modes of operation. For example, in case of reading out data from memory cells in a selected row (e.g., at a read operation and at a program verify operation), the page buffer circuit 130 senses and latches data bits from the memory cells in the selected row. In case of programming data in the memory cells of the selected row (e.g., at a program operation), the page buffer circuit 130 temporarily stores data bits from the external through a data input/output circuit 170.

A pass/fail check circuit 140 judges whether data bits nWD0-nWDm from the page buffer circuit 130 have the same value (e.g., pass data value) at the program verify operation. That is, the pass/fail check circuit 140 judges whether a program operation is successfully carried out (or whether threshold voltages of all memory cells in the selected row exist within a target threshold voltage distribution), based on the data bits nWD0-nWDm from the page buffer circuit 130 at the program verify operation. A program controller 150 includes a loop counter 151, which counts up a program loop number of the program cycle according to the judgment result of the pass/fail check circuit 140. For example, if the judgment result of a current program loop indicates program fail (or it indicates that at least one memory cell is not programmed), the loop counter 151 counts up the program loop number.

A program controller 150 controls a program loop time (or a program time) of each program loop based on a counted value of the loop counter 151. The program cycle consists of a number of program loops, each of which is divided into a program period and a program verify period. The program controller 150 may set a program time of a first program loop to be different from that of each of the remaining program loops. In the described embodiments, the program time of the first program loop is set to be longer than that of each of the remaining program loops. Program times of the remaining program loops are set to be the same. It should be apparent to those skilled in the art that the program times of the remaining program loops may alternatively be set so that they are different from one another. In this case, the program time of the first program loop was set longer than that of each of the remaining program loops.

A word line voltage generator circuit 160 is controlled by the program controller 150 and generates a program voltage as a word line voltage during a given program time in every program loop. The program voltage is supplied to a selected row via the row decoder circuit 120.

Herein, the program loop time includes a time (hereinafter, referred to as a program time) needed to perform a program operation and a time (hereinafter, referred to as a program verify time) needed to perform a program verify operation. Accordingly, the term “program time” refers to the time needed to perform the program operation.

As described above, the times necessary for performing program loops may be set differently from one another. In these embodiments, the program loop time (or the program time) of the first program loop is set to be longer than that of each of remaining program loops. In this program manner, it is possible to control the threshold voltage distribution of memory cells to be more densely distributed.

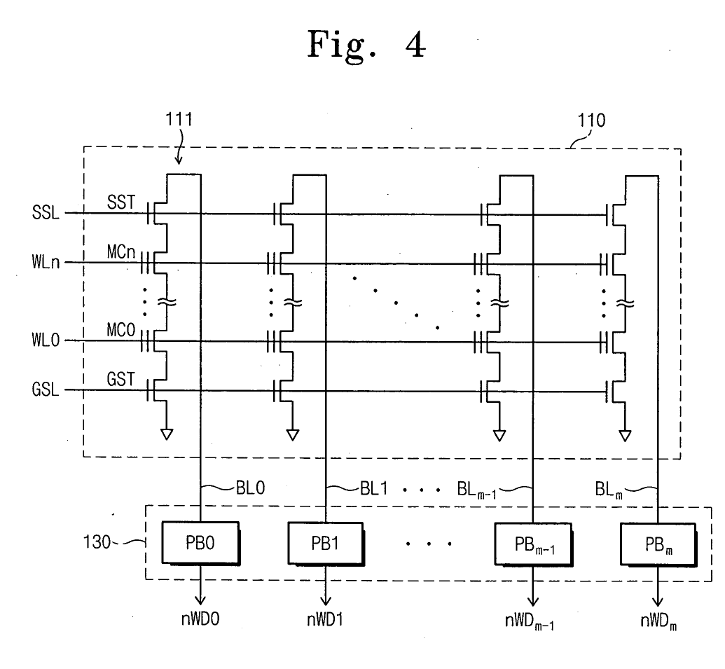

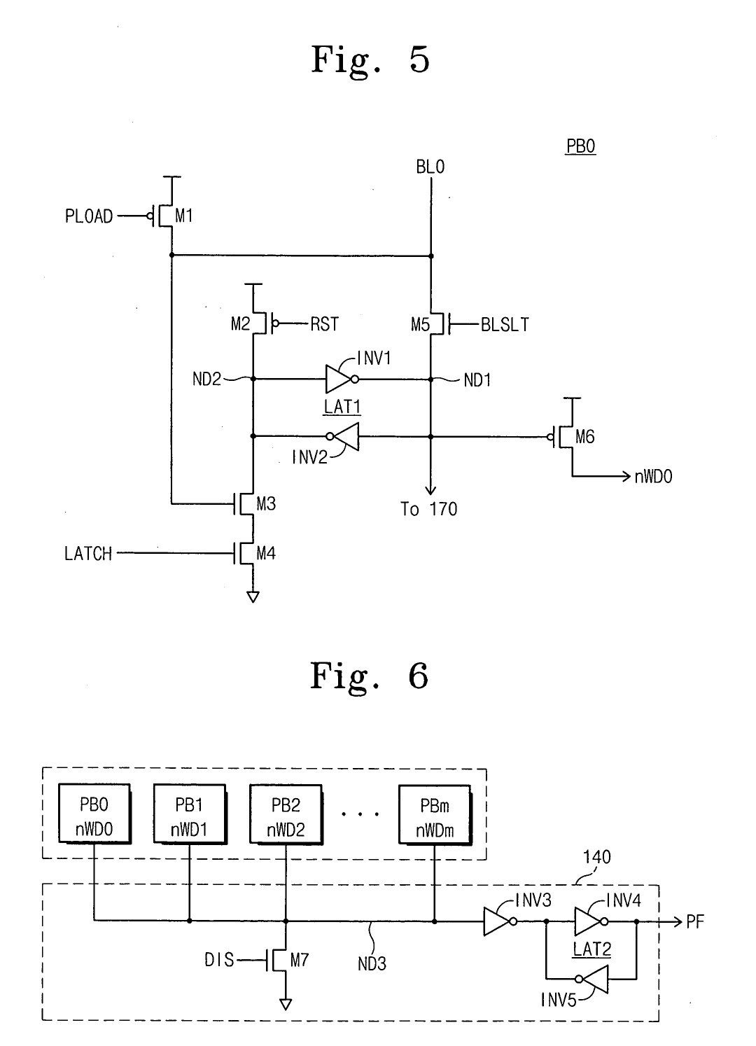

FIG. 4 is a schematic block diagram illustrating the memory cell array and the page buffer circuit of FIG. 3. FIG. 5 is a circuit diagram further illustrating the page buffer circuit of FIG. 4.

As illustrated in FIG. 4, a memory cell array 110 includes a number of strings 111, each of which has a string select transistor SST, a ground select transistor GST, and a number of memory cells (or memory cell transistors) MC0-MCn connected in series between the select transistors SST and GST. In each string, a gate of the string select transistor SST is connected to a string select line SSL, a gate of the ground select transistor GST is connected to a ground select line GSL, and gates of the memory cell transistors MC0-MCn are connected to corresponding word lines. The strings 111 are electrically connected to corresponding page buffers PB0-PBm via corresponding bit lines BL0-BLm.

The page buffers PB0-PBm are constructed in the same manner. As illustrated in FIG. 5, a page buffer PB0 includes PMOS transistors M1, M2, and M6, NMOS transistors M3, M4, and M5, and a latch LAT1 consisting of inverters INV1 and INV2, which are connected as illustrated in FIG. 5. It should be apparent that other embodiments of the invention may have page buffer structures that are different than that in FIG. 5. The latch LAT1 is reset via the PMOS transistor M2 during the program verify operation.

During the program verify operation, a voltage level of a bit line BL0 is determined according to a programmed/erased state of a corresponding memory cell. For example, when a memory cell is sufficiently programmed, current flow via the memory cell is cut off, so that a voltage level of the bit line BL0 goes high. When a memory cell is programmed insufficiently, current flows via the memory cell, so that a voltage level of the bit line BL0 goes to a low level. In the former case, when a control signal LATCH is activated high, a latch node ND2 of the latch LAT1 becomes low via the NMOS transistors M3 and M4. In the latter case, although the control signal LATCH is activated, the latch node ND2 of the latch LAT1 is maintained at an initial state (that is, a high level) because the NMOS transistor M3 is turned off. A data value nWD0 from the PMOS transistor M6 is determined according to a value thus latched and is transferred to a pass/fail check circuit 140 in FIG. 3. A high level of the latch node ND 1 indicates that a corresponding memory cell is sufficiently programmed up to a target threshold voltage, and a low level of the latch node ND1 indicates that the corresponding memory cell is insufficiently programmed up to the target threshold voltage.

FIG. 6 is a circuit diagram of illustrating the pass/fail check circuit of FIG. 3. As described above, when programming a memory cell, a program verify operation is carried out which judges whether a programmed memory cell has a target threshold voltage. Whether memory cells in a selected row are normally programmed is determined by values in latches LAT1 of page buffers PB0-PBm, which is carried out by the pass/fail check circuit 140.

Referring to FIG. 6, the pass/fail check circuit 140 is a wired-OR type pass/fail check circuit and includes an NMOS transistor M7, an inverter INV3, and a latch LAT2 consisting of inverters INV4 and INV5.

After program states of memory cells are latched in corresponding page buffers PB0-PBm, a node ND3 is set to a ground voltage via the NMOS transistor M7.

Output terminals nWD0-nWDm of the page buffers PB0-PBm, as described above, are determined by logic states of latch nodes ND1 in corresponding latches LAT1. For example, when the latch node ND1 has a high level of ‘1’, the PMOS transistor M6 is turned off. When the latch node ND1 has a low level of ‘0’, the PMOS transistor M6 is turned on. Herein, a high level of the latch node ND1 indicates that a corresponding memory cell is sufficiently programmed up to a target threshold voltage, and a low level of the latch node ND 1 indicates that the corresponding memory cell is insufficiently programmed up to the target threshold voltage. In the former case, the ND3 node is maintained at a low level, so that a pass/fail signal PF goes to a low level informing that a program verify operation is passed. In the latter case, the ND3 node has a high level via the PMOS transistor M6, so that the pass/fail signal PF goes to a high level informing that a program verify operation is failed.

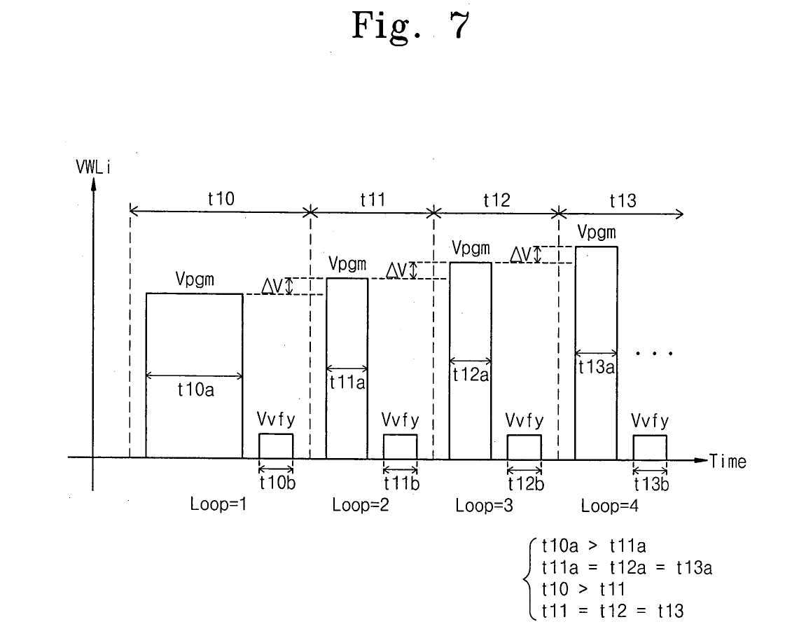

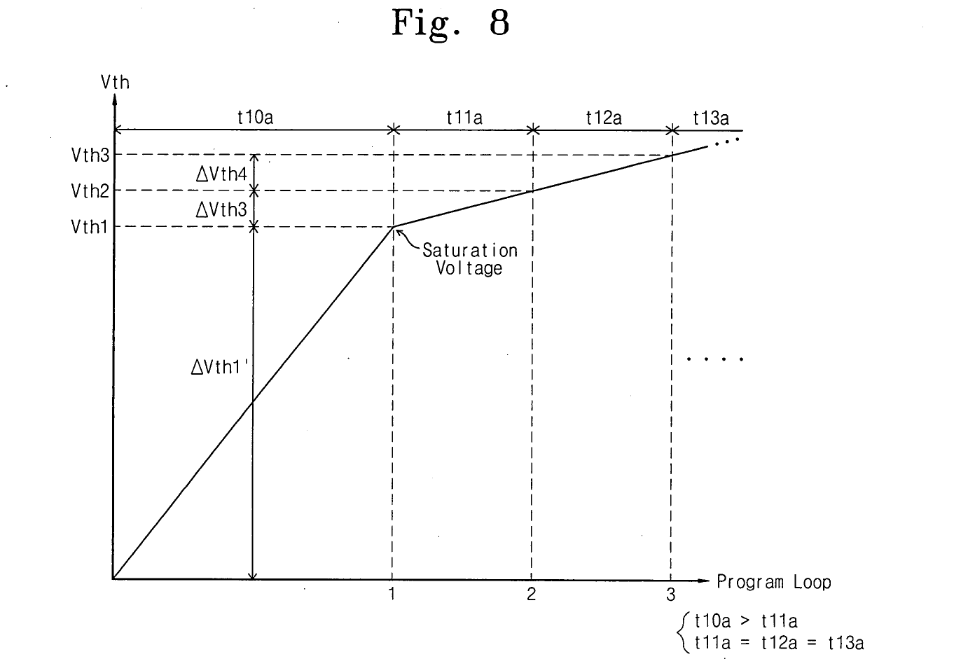

FIG. 7 is a timing diagram illustrating a program method according to some embodiments of the invention, and FIG. 8 is a diagram illustrating the threshold voltage variation of a memory cell according to the program method of FIG. 7.

According to some embodiments, the program cycle consists of a number of program loops, each of which is divided into a program period and a program verify period. As the program loops are repeated, a program voltage Vpgm is stepwise increased by a given voltage (ΔV). As is well known, before a program operation is carried out, data to be programmed is loaded on a page buffer circuit 130 via the data input/output circuit 170 of FIG. 3. If the program operation commences, bit lines BL0-BLm are set to a ground voltage (or a program voltage) or a power supply voltage (or a program inhibition voltage) according to the loaded data on the page buffer circuit 130, respectively. This operation is more fully described in U.S. Pat. No. 5,677,873 issued to Choi et al., entitled “METHOD OF PROGRAMMING FLASH EEPROM INTEGRATED CIRCUIT MEMORY DEVICES TO PREVENT INADVERTENT PROGRAMMING OF NONDESIGNATED NAND MEMORY CELLS THEREIN”, which is herein incorporated by reference.

After the data to be programmed is loaded, an actual program operation is carried out. Before the program operation is performed, a program controller 150 resets a loop counter 151, and an initial value of the loop counter 151 indicates a first program loop. Next, the program controller 150 sets a program loop time to t10 according to the initial value of the loop counter 151 informing the first program loop. Herein, the program loop time t10 comprises a time t10a (hereinafter, referred to as a program time) necessary for a program operation and a time t10b (hereinafter, referred to as a program verify time) necessary for a program verify operation. The program verify times of all the program loops are set to be the same (t10b=t11b=t12b=t13b).

A word line voltage generator circuit 160 generates the program voltage Vpgm during the program time t10a set by the program controller 150, and the program voltage Vpgm is supplied to a selected row (or a word line) via a row decoder circuit 120. As the program voltage Vpgm is supplied to the selected row and bit lines BL0-BLm are set to GND or VCC according to the loaded data, memory cells of the selected row are programmed during the program time t10a.

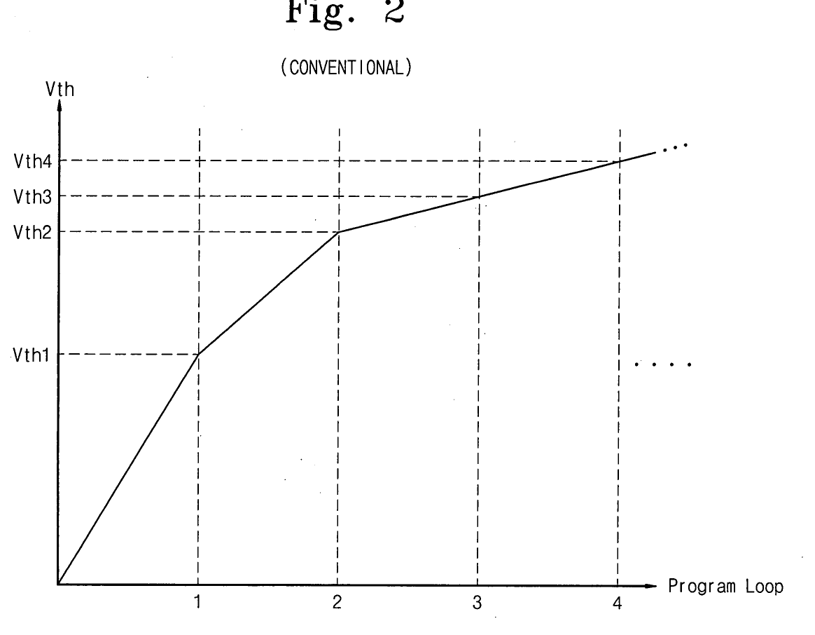

As was described above, the saturation voltage referred to FIG. 2 is the voltage level where the threshold voltage begins to increase at a constant rate with respect to increments of the program voltage Vpgm. Before the threshold voltage of a memory cell reaches the saturation voltage (or until a part of program loops is carried out), the threshold voltage increases at a non-constant rate with respect to increments of the program voltage.

To the contrary, according to some embodiments of the invention, the program time of the first program loop may be set to a time when a threshold voltage of a memory cell reaches a saturation voltage. Thus, as illustrated in FIG. 8, the program time t10a of the first program loop is set such that a threshold voltage of a memory cell increases at a constant rate up to the saturation voltage in the first program loop.

After the program operation of the first program loop is performed during the set program time, a program verify operation is carried out to judge whether threshold voltages of programmed memory cells are shifted in a desired threshold voltage distribution. As the program verify operation is accomplished in a well-known manner, logic levels of latch nodes ND1 in page buffers PB0-PBm are determined by the programmed states of corresponding memory cells. If the latch nodes ND1 all go to a high level, a pass/fail check circuit 140 outputs to the program controller 150 a pass/fail signal PF of a low level indicating that selected memory cells are sufficiently programmed. If at least one of the latch nodes ND1 has a low level, the pass/fail check circuit 140 outputs to the program controller 150 the pass/fail signal PF of a high level indicating that a current program operation is failed. The program controller 150 ends the program cycle when the pass/fail signal PF of the low level is received. On the other hand, the program controller 150 increases a count value of the loop counter 151 by one when the pass/fail signal PF of the high level is received. Then, the program controller 150 sets the program loop time to t11 according to the counted value of the loop counter 151. That is, a program time of the second program loop is set to t11a. The word line voltage generator circuit 160 generates the program voltage Vpgm during the program time t11a set by the program controller 150, and the program voltage Vpgm is supplied to the selected row via the row decoder circuit 120. Afterward, a program operation and a program verify operation of the second program loop are performed in the same manner as described above, which is repeated until all memory cells in the selected row are programmed sufficiently.

After a memory cell is programmed to the saturation voltage during a program time t10a of the first program loop, as illustrated in FIG. 8, a threshold voltage of the memory cell increases at a second constant rate with respect to increments of the program voltage in each of the remaining program loops. Thus, embodiments of the invention are capable of controlling a threshold voltage distribution to be more densely distributed by setting a program time of the first program loop to be longer than that of each of remaining program loops.

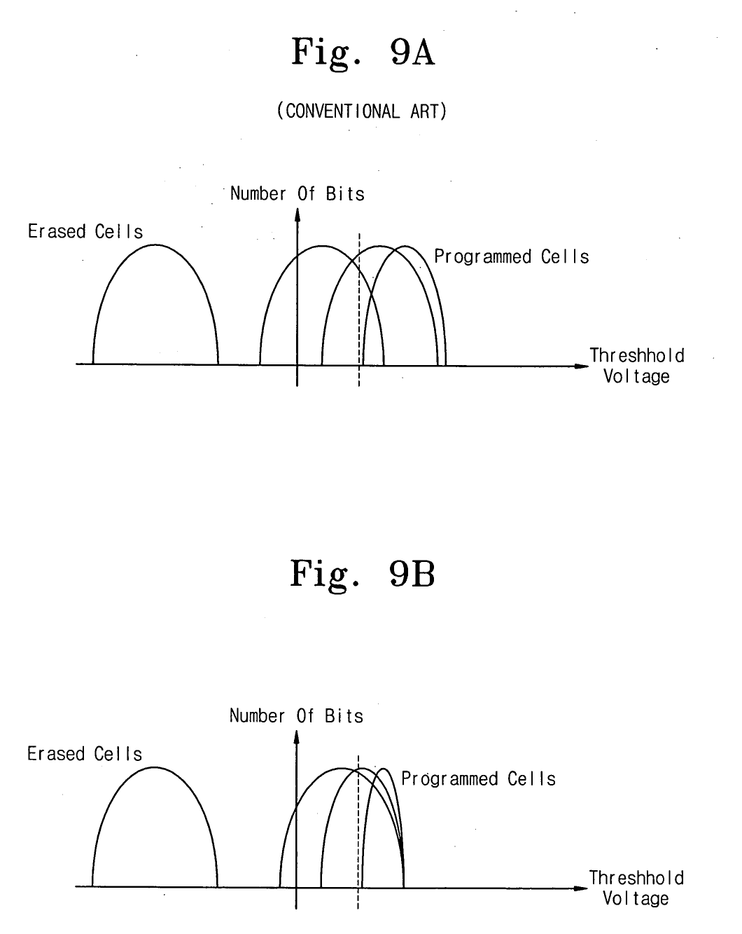

This improvement in the distribution of the threshold voltage may be seen by comparing FIG. 9A to FIG. 9B. FIG. 9A is a diagram illustrating the threshold voltage distribution according to the conventional program method, while FIG. 9B is a diagram illustrating the threshold voltage distribution according to some embodiments of the invention.

The invention may be practiced in many ways. Exemplary, non-limiting descriptions of some embodiments of the invention are provided in the following paragraphs.

In accordance with some embodiments of the invention, a non-volatile memory device includes a number of memory cells and a word line voltage generator circuit. The word line voltage generator circuit generates a program voltage to be applied to the memory cells every program loop of a program cycle. Each program loop includes a program period and a program verify period, the program time of each of the program loops is defined by the program period. The word line voltage generator circuit generates the program voltage for a program time period. The program time of a first program loop may be set differently from that of each of the remaining program loops. According to some embodiments, the program time of the first program loop is longer than that of each of the remaining program loops. The remaining program loops may be set to the same program time. Alternatively, the program times of the remaining program loops may be different from one another.

The non-volatile memory device further includes a program controller that controls the word line voltage generator circuit so that a program time of the first program loop of a program cycle is set to be longer than that of each of remaining program loops of the program cycle.

The invention has been described using exemplary preferred embodiments. However, it is to be understood that the scope of the invention is not limited to the disclosed embodiments. To the contrary, it is intended to cover various modifications and similar arrangements. The scope of the claims, therefore, should be accorded the broadest interpretation so as to encompass all such modifications and similar arrangements.

1. A non-volatile memory device comprising:
memory cells that are structured to be programmed during a program cycle that is divided into program loops; and
a word line voltage generator circuit structured to generate a program voltage that is applied to the memory cells every program loop during a program time of the program loop, a program time of one of the program loops being different than a program time of each of the remaining program loops.

2. The non-volatile memory device of claim 1, wherein a program time of a first program loop is different than a program time of each of the remaining program loops.

3. The non-volatile memory device of claim 2, wherein the program time of the first program loop is longer than that of each of the remaining program loops.

4. The non-volatile memory device of claim 3, wherein the program times of the remaining program loops are the same.

5. The non-volatile memory device of claim 3, wherein the program times of the remaining program loops are different from one another.

6. The non-volatile memory device of claim 1, wherein each of the program loops comprises a program period and a program verify period, the program time of each of the program loops being defined by the program period.

7. The non-volatile memory device of claim 1, further comprising a program controller for controlling the word line voltage generator circuit so that a program time of a first program loop is longer than that of each of the remaining program loops.

8. A non-volatile memory device comprising:
a word line voltage generator circuit for generating a program voltage during a program time of each of a plurality of program loops; and
a program controller for controlling the word line voltage generator circuit so that a program time of a first program loop is different from a program time of each of the remaining program loops.

9. The non-volatile memory device of claim 8, wherein the program time of the first program loop is longer than that of each of the remaining program loops.

10. The non-volatile memory device of claim 9, wherein the program times of each of the remaining program loops are the same.

11. The non-volatile memory device of claim 9, wherein the program times of the remaining program loops are different from one another.

12. The non-volatile memory device of claim 8, wherein each of the program loops comprises a program period and a program verify period, the program time of each of the program loops being defined by the program period.

13. The non-volatile memory device of claim 8, wherein the program voltage is supplied to a selected word line during the respective program loops.

14. A non-volatile memory device comprising:
an array of memory cells arranged in rows and columns;
a word line voltage generator circuit for generating a program voltage;
a row selector circuit for selecting one of the rows to drive the selected row with the program voltage; and
a program controller for controlling the word line voltage generator circuit so that the program voltage is supplied to the selected row for a first program loop of a program cycle that has a program time that is longer than a program time of each of the remaining program loops of the program cycle.

15. The non-volatile memory device of claim 14, wherein a program time of each of the remaining program loops are the same.

16. The non-volatile memory device of claim 14, wherein a program time of each of the remaining program loops are different from one another.

17. The non-volatile memory device of claim 14, wherein each of the program loops comprises a program period and a program verify period, the program time of each of the program loops being defined by the program period.

18. The non-volatile memory device of claim 17, further comprising:
a page buffer circuit for reading out data bits from memory cells in the selected row during the program verify period; and
a pass/fail check circuit for checking whether all of the read-out data bits indicate a program state.

19. The non-volatile memory device of claim 18, wherein the program controller comprises a loop counter for counting up a program loop number according to an output of the pass/fail check circuit.

20. The non-volatile memory device of claim 19, wherein the program controller is structured to control the program voltage generator circuit in response to a counted value of the loop counter.

21. A program method of a non-volatile memory device comprising:
performing a first program loop having a first program time; and
performing a second program loop having a second program time.

22. The method of claim 21, wherein performing the first and the second program loops comprises:
programming memory cells with data to be programmed; and
verifying whether the memory cells are normally programmed.

23. The program method of claim 21, wherein the first program time is longer than the second program time.

24. The program method of claim 21, further comprising performing a third program loop having the second program time.

25. The program method of claim 21, further comprising performing a third program loop having a third program time.

26. The program method of claim 21, wherein each of the program loops comprises a program period and a program verify period, the program time of each of the program loops being defined by the program period.

27. A program method of a non-volatile memory device comprising:
programming a memory cell so that a threshold voltage of the memory cell is shifted to a saturation voltage from a reference voltage during a first program loop; and
after the first program loop, programming the memory cell so that the threshold voltage of the memory cell is shifted to another voltage from the saturation voltage, a difference between the another voltage and the saturation voltage being lower than a difference between the saturation voltage and the reference voltage.

28. The program method of claim 27, wherein the reference voltage is a threshold voltage of an erased memory cell.
